(19) United States
(12) Patent Application Publication
(10) Pub. No.: US 2022/0200517 A1
(43) Pub. Date: Jun. 23, 2022

(54) SOLAR POWER CLADDING

(71) Applicant: B.XO GROUP LTD, London (GB)

(72) Inventor: James David Birch, London (GB)

(21) Appl. No.: 17/601,632

(22) PCT Filed: Apr. 6, 2020
(86) PCT No.: PCT/GB2020/050901

§ 371 Date: Oct. 5, 2021

(30) Foreign Application Priority Data
Apr. 5, 2019 (GB) 1904888.3

(51) Int. Cl. H02S 20/25; H01L 31/0236; H01L 31/048; H02S 40/34; H02S 40/42

(52) U.S. Cl. CPC H02S 20/25; H01L 31/02366; H02S 40/42; H02S 40/34; H01L 31/0481

(57) ABSTRACT

The present invention relates to a solar cladding member comprising a solar power module, the solar power module encapsulated in a polymeric material and comprising a first surface arranged to be exposed to sunlight in use and an opposing surface affixed to a substrate. An electrical junction is configured to connect the solar power module to an electrical system for transfer of electrical power from the solar power module, the electrical junction located on the opposing surface of the solar power module adjacent the substrate. The substrate comprises a cavity facing the opposing surface of the solar power module, the cavity bounded by the substrate, and configured to accommodate and seal the electrical junction therein.

The present invention relates to solar power cladding systems, and cladding members for such systems, e.g. solar power tiles.

It is well known to install solar power systems onto rooves or other static structures. Systems typically comprise a photovoltaic (PV) cell covered with a protective glass screen. However, such systems are can very heavy and fragile. This can lead to problems when transporting or installing the systems, as they can be prone to damage, or may be difficult to install due to the large weight. The system requires a complex framework structure to support the PV cells and accessing the electrical connections between the cells (i.e. when replacing a cell) can be difficult.

Such systems look very different to conventional roofing materials (e.g. slates/tiles) and so may not look aesthetically pleasing. This may pose an issue, especially in sensitive locations, for example, in conservation areas or historic buildings. It is also typical that a conventional roof is installed and the solar power system is mounted over the conventional roof. Thus the PV cells are attached to, but do not form part of, the roof or cladding itself.

The weight and structural characteristics of conventional solar panels makes them unsuitable for various other cladding applications.

Furthermore, PV cells tend to become less efficient as the temperature of the cells increase. Therefore, as the solar cell heats, less electricity is generated. This may further cause damage to the system, for example, through heat degradation, or differential thermal expansion.

Whilst a glass screen over the PV cells helps to maintain temperature within limits due to the reflection of a portion of the incident light, this reduces the maximum possible efficiency of the cells. This increases also increases the glare produced by the cells, which may decrease the aesthetic qualities of the tile.

GB2517914 discloses an example of a solar roof tile that can form part of the roof tile structure. However, the installation of such tiles is a complex and time consuming process, with each tile needing to be connected up in sequence using wired connectors depending from the rear of the tile. If the wired connector becomes damaged, the entire tile becomes unusable. The location of the wired connections can be problematic when it is considered that the tile needs to be mounted and fastened on its rear side to a supporting framework.

Despite significant efforts being expended to protect against the ingress of moisture, the thermal cycling of the tile in use causes stresses in the tile structure which can leave the tile prone to moisture ingress over time. Thermal stresses over prolonged periods of use can degrade the tile structure more generally and cut short its potential operational life.

The use of a conventional concrete substrate has been found by the inventor to act as an insulator, resulting in higher operating temperatures being achieved by the PV cells and reducing the power output over the lifespan of the tile.

It is an aim of the present invention to overcome or ameliorate one or more of the above problems. According to a first aspect, there is provided a solar cladding member comprising: a solar power module, the solar power module encapsulated in a polymeric material and comprising a first surface arranged to be exposed to sunlight in use and an opposing surface affixed to a substrate; an electrical junction configured to connect the solar power module to an electrical system for transfer of electrical power from the solar power module; the electrical junction located on the opposing surface of the solar power module adjacent the substrate; where the substrate comprises a cavity facing the opposing surface of the solar power module, the cavity bounded by the substrate, and configured to accommodate and seal the electrical junction therein.

One or both of the surface of the solar power module adjacent the substrate or the surface of substrate adjacent the power module may comprise a roughened texture.

According to a second aspect, there is provided a solar cladding member comprising: a solar power module encapsulated in a polymeric material and affixed to a substrate; where the substrate comprises a plurality of recesses at least partially extending through the substrate behind the solar power module for cooling of the solar power module in use.

Preferably, the recesses comprise through holes, the through holes extending between opposing sides of the substrate.

Preferably, an array of the recesses is only located in portions of the substrate overlaid by the solar power module.

Preferably, the diameter and/or the packing density of recesses varies across the substrate.

Preferably, the diameter and/or packing density of the holes in a given area of the substrate is proportional to the heat density in the given area of the substrate.

Preferably, the solar cladding member is devoid of an outer glass layer for the solar power module.

The recesses may improve the surface area of the substrate for convective cooling and/or reduce the thermal mass of the substrate acting to insulate the rear of the solar power module.

The solar power module and/or cladding member may be devoid of an outer glass layer covering the module or cells thereof. The cladding member may be glass free. A protective facia/cover layer may be provided.

According to a further aspect, there is provided a solar cladding member comprising: a solar power module encapsulated in a polymeric material and affixed to a substrate; where the substrate comprises male and female terminals for connection to a wider electrical system, the terminals being embedded in the substrate and facing a peripheral edge of the solar cladding member.

Further optional features of the invention are defined in the accompanying claims.

Practicable embodiments of the invention are described in further detail below with reference to the accompanying drawings, of which:

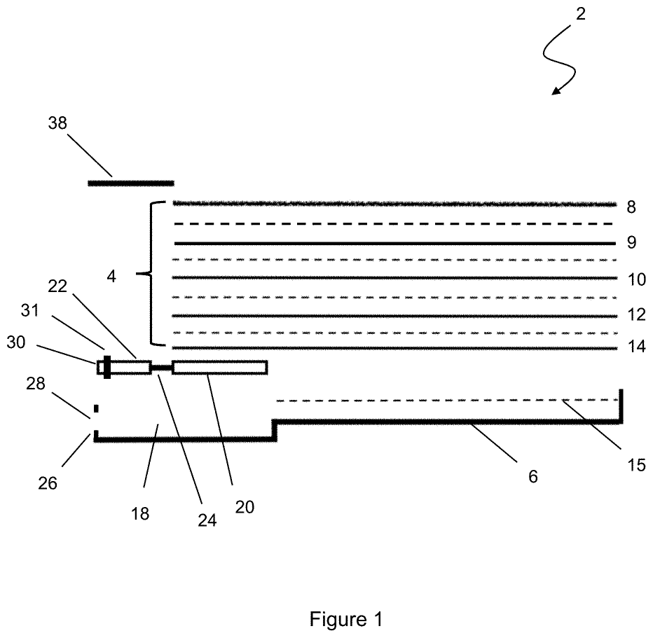

FIG. 1 shows a section through a solar tile according to an example of the disclosure.

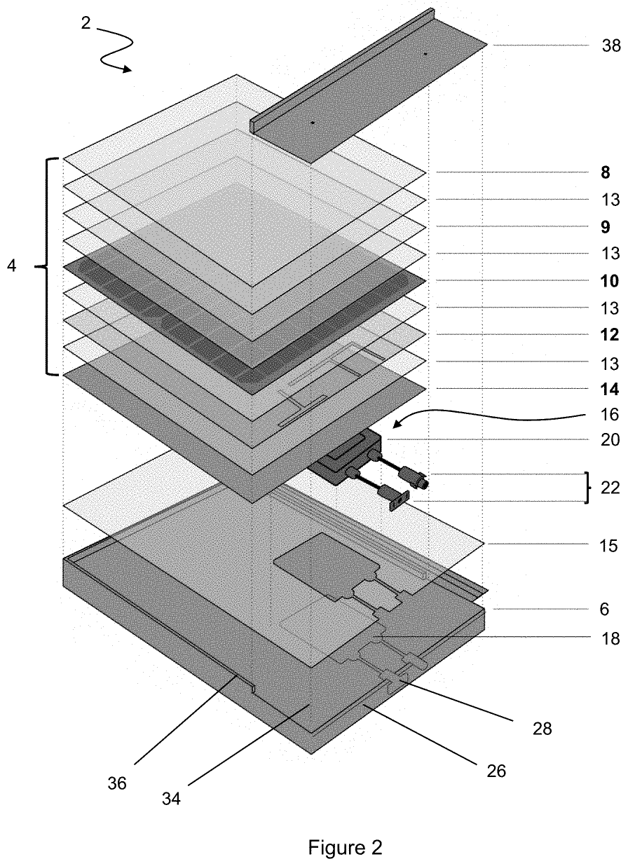

FIG. 2 shows an exploded three-dimensional view of the solar tile.

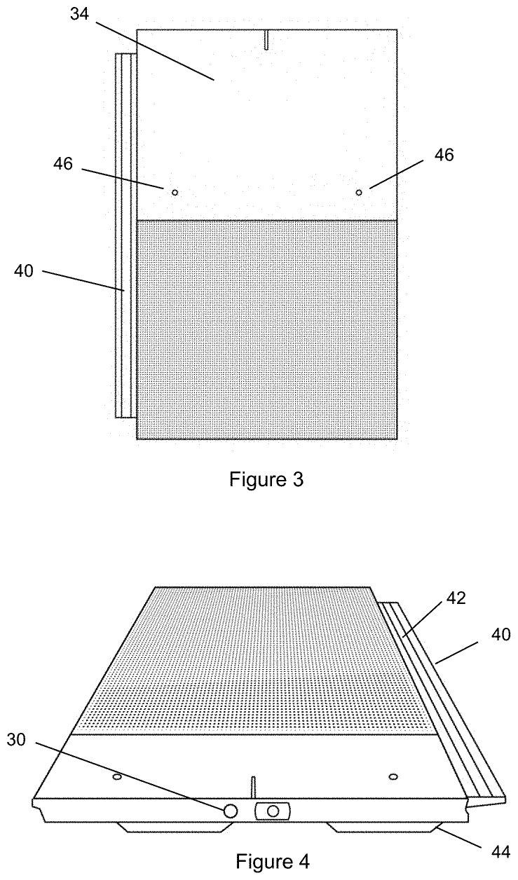

FIG. 3 shows a front view of a solar tile according to a further example of the disclosure.

FIG. 4 shows a perspective view of an end of the solar tile of FIG. 3.

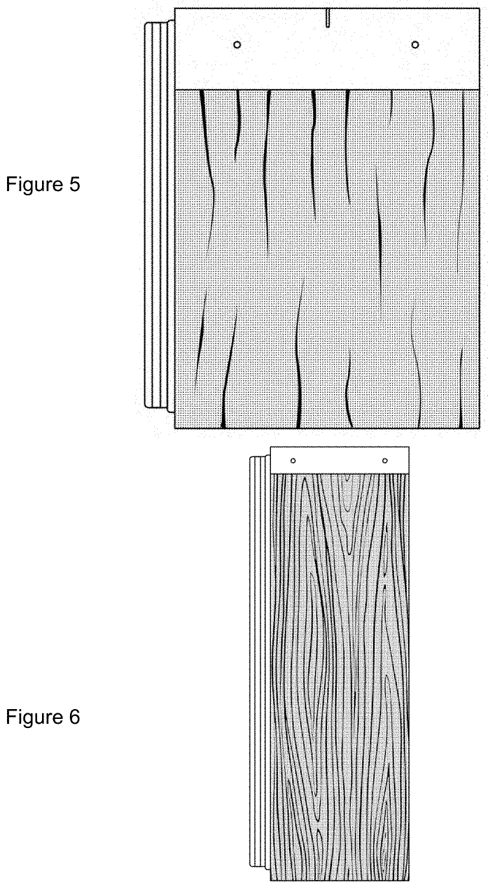

FIG. 5 shows a front view of a first example of a textured tile.

FIG. 6 shows a front view of a second textured tile.

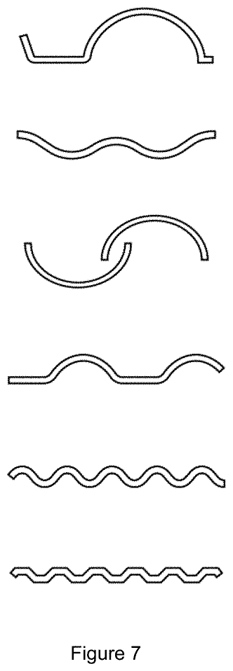

FIG. 7 shows various alternative sectional profiles of the substrate for a solar tile.

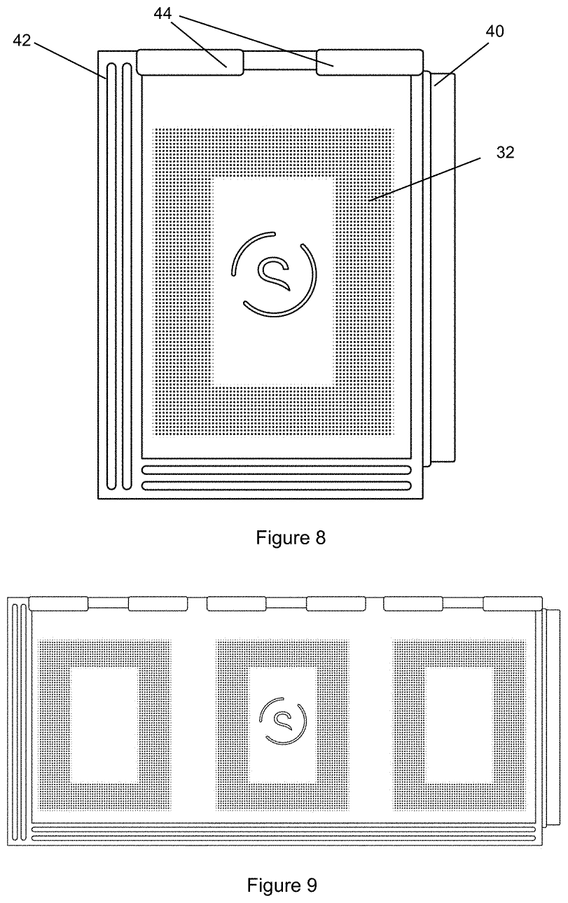

FIG. 8 shows a rear view of an example of the solar tile.

FIG. 9 shows a rear view of an example of a multi solar tile.

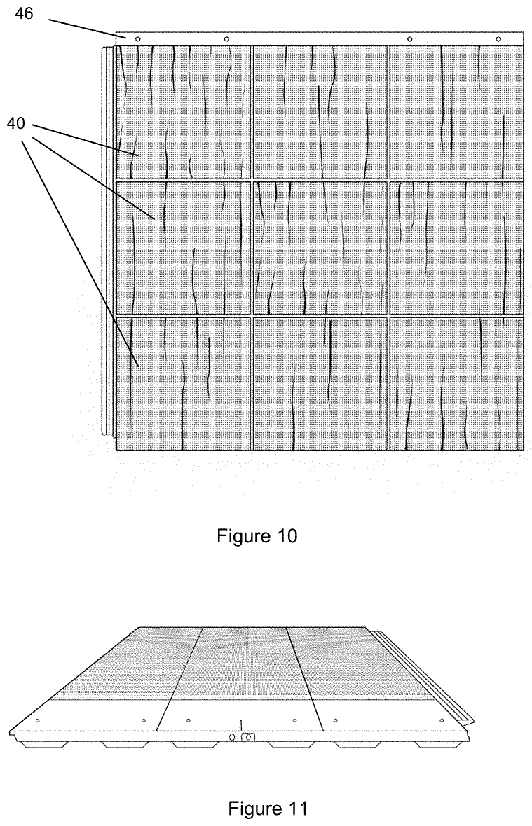

FIG. 10 shows a front view of a further example of a multi solar tile.

FIG. 11 shows a perspective view of an end of a multi solar tile.

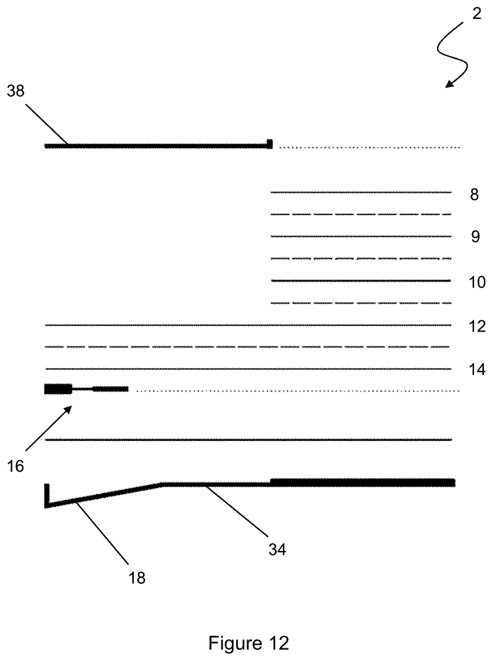

FIG. 12 shows a section through a solar tile according to a further example of the disclosure.

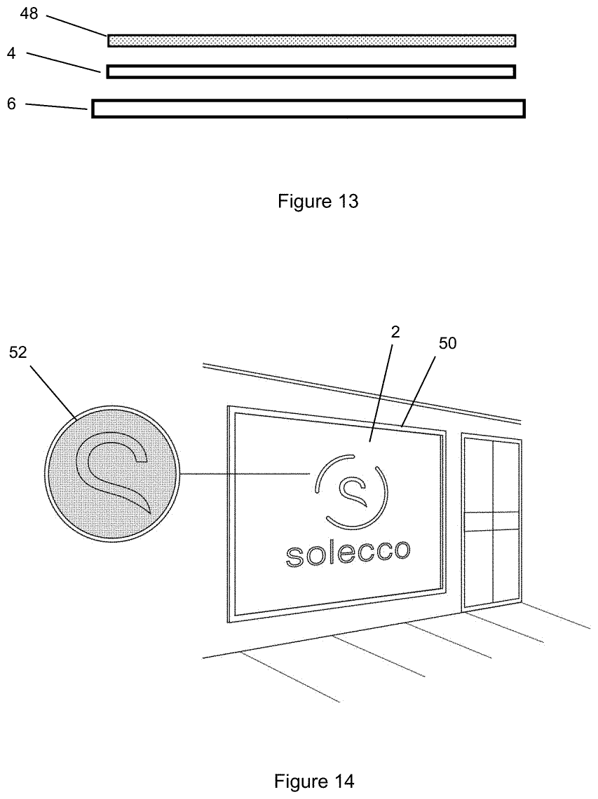

FIG. 13 shows a section view through a further example of solar cladding member.

FIG. 14 shows an example application of the example of FIG. 13.

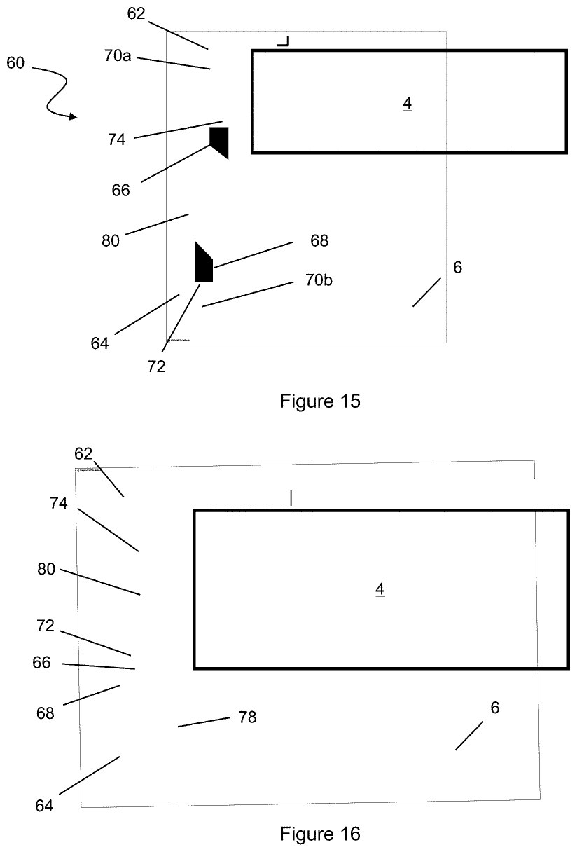

FIG. 15 shows a first embodiment of a clip system.

FIG. 16 shows a second embodiments of the clip system.

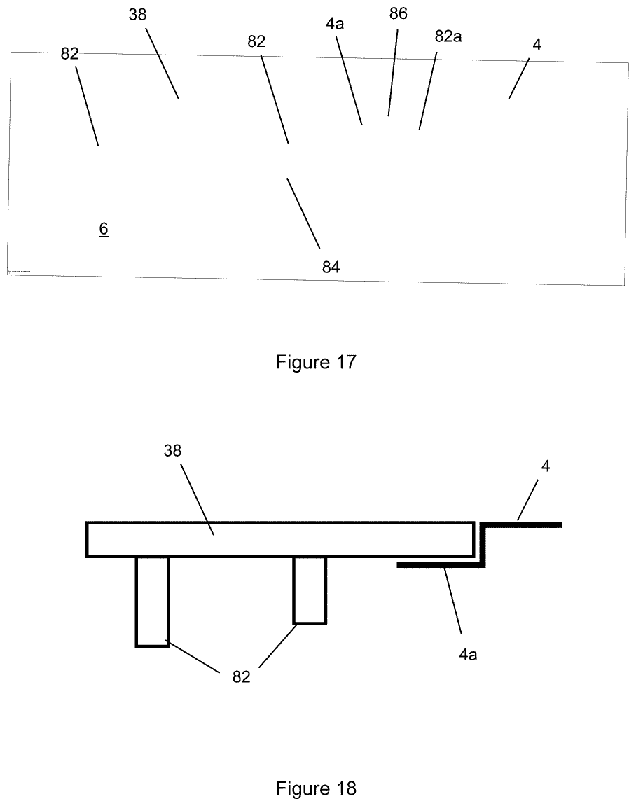

FIGS. 17 and 18 shows a close up view of a facia arrangement.

FIGS. 1-7 show various examples of a cladding member in the form of a tile 2. The tile 2 is suitable for use as a roof tile but could be used for various other applications involving cladding of a structure.

The roof tile 2 comprises a solar power module 4. The solar power module 4 comprises multi-layered structure offering a large surface area relative to its depth. The solar power module 4 comprises a solar power layer 10 configured to convert solar power (i.e. electromagnetic radiation) into usable electrical power.

The solar power layer comprises one or more solar power cells, typically an array of cells arranged in a common plane. The solar power cell may comprise a photovoltaic (PV) cell such as: monocrystalline silicon; polycrystalline silicon; hybrid (e.g. a combination of monocrystalline and amorphous silicon); thin film; organic; inorganic; perovskite; graphene; Copper Indium Gallium Diselenide (CIGS) cells; or other conventional PV technologies.

Additionally or alternatively, the solar power layer 10 comprises one or more cell configured to convert the heat captured from the solar power into usable electrical power, for example, using a thermoelectric/thermovoltaic device or a heat exchanger. The layer 10 may be referred to as a solar cell layer.

The solar power layer 10 may comprise a plurality of solar power cells, for example, arranged in a one or two-dimensional array to substantially span the entire area of the solar power layer 10 and/or module 4.

The solar power module 4 comprises a first layer 8 arranged on the uppermost surface of solar module 4 and configured to be exposed to the external environment in use. The first layer 8 comprises a substantially transparent material to allow light to pass through and be collected the solar power cells. The first layer 8 may be water resistant and/or ultraviolet radiation (UV) resistant. The layer 8, or the exposed side thereof, may be treated to improve the resistance properties of the solar cladding unit to ultraviolet radiation (UV), for example through UV stabilisation or through use of UV-resistant coatings, films, layers or other materials.

The first layer 8 may comprise flame resistant and/or flame retardant materials.

The first layer 8 comprises a polymeric material. The polymeric material may comprise an acrylic film.

The first layer 8 comprises an impact and/or a stress resistant material to protect the solar power layer 10 from impact and/or mechanical damage.

As shown in FIGS. 3 to 6, the first layer 8 may comprise a texture on uppermost surface thereof.

The textured surface may comprise a first texture type, e.g. being a generally uniform or repeating pattern over the whole surface area of the outer surface layer 8.

The first surface texture may comprise a length scale that is relatively small (e.g. the individual features of the texture are less than 3 mm, 2 mm or 1 mm in size), which may be referred to as a ‘microtexture’ herein. The first surface texture is configured to allow the first layer 8 to capture more light. Without being bound by theory, the uneven surface of the texture is proposed to increase the available surface area when incident sunlight is not perpendicular to the plane of the surface. Additionally or alternatively, the uneven surface texture is proposed to increase the angle of incidence between the surface and the light (particularly when the light approaches the tile 2 at an acute angle), thereby increasing the transmission of light through the first layer 8 and to the solar power layer 10.

When light reaches the solar power layer 10, a portion of the light is reflected back towards the first layer 8. It is further believed the uneven surface increases the amount of the reflected light that is reflected back by the first layer 8 towards the solar power layer 10, thereby increasing the amount of light captured.

The first/micro texture may reduce specular glare, thus giving the tile a matte finish.

The first/micro texture may comprise a substantially repeating/regular pattern. In other embodiments, the first/micro texture may comprise a non-repeating/irregular texture. Even is an irregular surface texture is used, it may be irregular on a small length scale but generally evenly distributed when viewed on a macroscopic length scale over the whole area.

The first/micro texture may comprise a stippled and/or dimpled texture (i.e. plurality of repeating protrusions/dimples). An array of discrete protrusions/dimples may be used. Other arrangements of peaks and troughs may be used, e.g. including elongate grooves or ridges running along the surface. Elongate peaks/troughs may be parallel or intersecting and/or may be straight or of varying regular/repeating or irregular direction. A riven or rippled surface effect may be used.

The surface texture of the outer surface may be formed using a variety of techniques, such as, for example, embossing, roller imprinting, sheet material compression, thermal moulding, reverse imprint moulding, press stamping, or other such suitable techniques. In other examples, the top surface texture and/or pattern may be created using additional materials disposed and adhered onto it. In such a case, the additional materials disposed should be selected so to not inhibit or otherwise impact the performance of the solar module. Surfacing elements might include polymer granules with high transmittance to solar radiation can be applied to the top surface.

The texture may be applied when the surface layer is in a molten or softened/malleable state, e.g. at elevated temperature.

The surface texture may be produced by impressing the desired pattern into the layer using an opposing impression/press member. In current embodiments, it has been found that a textile may be used to form the impression. That is to say a suitably stiff/coarse textile structure (for example, hessian) can be used to produce the desired effect in the polymer layer of the power module 4, at least when softened. A woven textile has been found to be particularly apt for providing a suitable surface pattern of the desired depth and length scale.

Additionally or alternatively, the surface texture may comprise a second texture, e.g. a macrotexture of greater length scale than that of the first texture (e.g. features greater than 1 mm, 2 mm or 3 mm in size). The second/macro texture may be configured to mimic a natural/conventional tile material. For example, the macrotexture is configured to mimic one or more of: slate (FIG. 5); wood grain (FIG. 6); concrete; terracotta; granite; other stone, such as limestone; or other conventional architectural materials.

The second texture may or may not be irregular. The second texture may be applied primarily for aesthetic purposes. However the macroscopic texturing of the top surface, for example, that of a woodgrain texture, can also provide advantageous solar performance functions as described above for the first texture. Accordingly, it may be that the second texture is used without also requiring the first texture. The second texture may be applied using any of the techniques described herein.

The solar power module 4 comprises a second layer 9 located inwards from the first layer 8. The second layer 9 comprises a substantially transparent material to allow light to pass through and be collected the solar power cells. The second layer 9 may be water resistant and/or UV resistant e.g. instead of, or in addition to the similar properties of the first layer 8.

The second layer 9 comprises a polymeric material. The polymeric material may comprise a fluoropolymer, for example, ethylene tetrafluoroethylene (EFTE). In some examples, this layer may be provided as the textured outer layer, e.g. in the absence of layer 8.

The solar module 4 may comprises an electrical connection layer 12, e.g. provided as a printed circuit board (PCB) layer of the module structure. The electrical connection layer 12 is located on an inward side of the solar power layer 10, such that the electrical connection layer 12 does not block light entering the solar power layer 8. That is to say the electrical connection layer 12 is beneath the layer 10 and/or on the opposing side of the layer 10 from layer 8 or 9. In some embodiments, the electrical connection layer is substantially transparent/translucent.

The electrical connection layer 12 is electrically connected to the solar power layer 10 and/or the solar power cells to collect the electrical power generated therein. The electrical connection layer 12 provides electrical conductors to act as connectors/contacts for attachment of positive/negative connectors as will be described below. The electrical connection layer 12 typically comprises control circuitry configured to control and/or regulate the electrical power (e.g. regulate the voltage) output of the solar cells.

The solar module 4 comprises a backing layer 14. The backing layer 14 forms the lowermost layer of the solar module 4. The backing layer 14 is substantially rigid and is configured to provide structural support to the solar power module 4.

The backing layer 14 may comprises a polymeric material with a high weather resistance. The polymeric material may comprise a fluoropolymer, for example, polyvinyl fluoride (PVF). The backing layer 14 may comprise an electrically insulating material to prevent the leak of electrical current therefrom.

Additionally or alternatively, the backing layer 14 comprises a thermally conductive layer configured to transfer heat from the solar power layer 10. The thermally conductive layer may comprise a metallic material, for example, copper or aluminium.

The layers of the solar power module 4 are bonded using a bonding layer 13 interposed therebetween. The bonding layer comprises a substantially transparent adhesive. The bonding layer may comprise ethylene-vinyl-acetate (EVA) and/or polyvinylbuterol (PVB). A bonding layer may be interposed between each layer 8, 9, 10, 12, 14 and its adjacent layer(s). Any, or any combination, of bonding layers 13 may be a continuous and/or uniform layer, e.g. spanning the entire module area.

One or more bonding layer may comprise an incomplete layer, e.g. covering only a portion of the module area and/or having one or more discontinuity therein. Different continuous and discontinuous bonding layers 13 may be used depending on whether electrical/thermal conduction is desirous between adjacent layers, e.g. for layers above the solar cell layer 10.

In other embodiments, two or more layers of the solar power module 4 are in direct contact with one another.

Depending on material selection, the bonding layers 13 may provide sealing, cushioning and/or insulating properties. The same or different bonding layers 13 may be used as required, e.g. being of different materials and/or layer thicknesses.

The first layer 8 and/or the second layer 9 and/or the backing layer 14 may overlap the edges of the solar power layer and/or the PCB. The first layer 8, the second layer 9 and the backing layer 14 surround and encapsulate the solar power layer 8 and the PCB 12 (where present) to prevent the ingress of moisture etc. and to form a substantially integral/encapsulated solar power module 4.

The solar power module 4 comprises an electrical junction 16. The electrical junction 16 is configured to transfer electrical power generated by the solar power layer 10 from the solar power module 4, e.g. to an external power supply system (i.e. to supply electrical power to the building, or other structure). The electrical junction 16 comprises discrete electrical pathways for both the positive and the negative current.

The electrical junction 16 is electrically/conductively connected to the electrical connection layer 12, e.g. to electrical contacts thereof, which may be on the underside of the electrical connection layer 12.

The electrical junction 16 is mounted to the lowermost surface of the solar power module 4 adjacent the substrate (e.g. the back plate 14) and extends therefrom. The electrical junction 16 may be mounted adjacent an edge portion of the solar power module 4 and/or at least a portion of the electrical connection 16 extends substantially along the plane of the module.

The electrical junction 16 may comprise a junction box 20. The junction box 20 is configured to accommodate a plurality of electrical connections/contacts from the electrical connection layer 12 and collate the electrical connection to provide a singular electrical connection point, i.e. for positive and negative connections. The junction box 20 comprises at least one diode/diode circuit configured to maintain the correct parity of the positive and negative electrical current pathway. The diode may allow each of the power cells or operate independently, for example, during times of partial shading or electrical fault of one or more cells. The junction box 20 may comprise additional control and/or regulation circuits to control/regulate the current and/or voltage through the electrical connection 16.

The junction box 20 comprises an exterior/outer housing surrounding the electrical components (i.e. the diode and control circuits etc.). The housing is configured to provide a sealed barrier to prevent moisture etc. entering the junction box 20 and damaging the electrical components. The housing may be sealed directly to the underside of the backing layer/plate 14, which may have one or more opening therein, within the perimeter of the junction box 20 housing to permit electrical connection with the electrical connection layer 12.

The electrical junction 16 comprises at least one electrical terminal 22 configured to receive an external electrical terminal to transfer electrical power therebetween. The electrical terminals may comprise male/female ‘plug’ type connectors, preferably, with an individual electrical terminal 22 for the positive and negative electrical connections. The use of different male (positive) and female (negative) connectors of the type described herein ensures the correct mating polarity of connections in the connection series and prohibits connection mistakes during installation, e.g. improving the speed and ease of the installation process.

The electrical junction 16 may comprise at least one electrical lead 24 to operatively connect the junction box 20 to the electrical terminal 22 and transfer electrical power therebetween. The electrical lead 24 may comprise a conventional electrical wire/cable, i.e. within a sheath.

In some embodiments, the junction box 20 is not present and the electrical lead 24 is directly connected to the solar power module 4.

In some embodiments, the electricals leads 24 are not present and the electrical terminal 22 is directly connected to/integrally formed with the junction box 20.

In some embodiments, neither the junction box 20 and the electrical leads are present, and the electrical terminal 22 is connected directly to the solar power module 4.

In the absence of a junction box 20, any functions performed by the junction box 20 are performed by the electrical connection layer 12 (e.g. within the PCB) or a component external to the solar tile 2.

The solar module 4 is attached/affixed as an encapsulated module to a substrate 6. The substrate 6 is configured to provide structural rigidity to the solar tile so that the tile can be attached to a support structure, such as a supporting frame, in use. The solar power module 4 conforms to the upper surface of the substrate 6. The substrate 6 provides a base panel for the cladding member, i.e. tile 2 as a whole.

The substrate 6 may be attached to the support structure using a plurality of fastening mechanisms/members. The fastening mechanism engages the substrate rather than solar power module 4, thus preventing/reducing damage of the solar power module 4.

The substrate 6 may be configured to emulate a conventional tile material (i.e. conventional stone or ceramic tiles). The tile may be shaped in the style of a conventional roof or wall tile.

In some embodiments, the substrate 6 is substantially flat (for example to emulate a flat tile). In such a case, the solar power module 4 is substantially flat and the solar power cell comprises a rigid power cell material, such as monocrystalline silicon, polycrystalline silicon or a hybrid (e.g. a combination of monocrystalline and amorphous silicon).

In other embodiments, the substrate 6 comprises a non-flat profile, for example, to emulate: a roman tile; a pantile; barrel tile; a Spanish tile; or other curved/polygonal tile. Various possible profiles for the substrate are shown in FIG. 7. The substrate may be curved/arched in form in whole or in part. Additionally or alternatively, the substrate may comprise a repeating, e.g. curved or angular, waveform. In such examples the profile of the solar power module 4 is configured to conform to the shape of the substrate 4. The solar power cell may comprise relatively flexible power cell materials in this regard, for example, thin film or organic cells.

In some embodiments, the substrate may comprise large panels or sheets, for example, the substrate may comprise a corrugated sheet suitable for providing large segments a roof.

The substrate is formed by a moulding process to allow one or more features to be integral therewith as will be described below, i.e. in addition to the general flat or curved sectional profile of the substrate.

The substrate 6 may have an attachment formation 40 configured to allow attachment of the substrate 6 to the substrate of an adjacent substrate/tile. The attachment formation 40 comprises a flange portion depending from one or two sides/edges of the substrate, i.e. adjacent sides.

The attachment formation 40 may comprise one or more elongate grooves and/or ribs 42, e.g. running along/adjacent a respective side of the substrate.

The substrate 6 may have a complimentary attachment formation, e.g. one or more elongate groove and/or rib 42 on a second/opposing side thereof. the complimentary attachment formation can be seen on the underside of the substrate in FIG. 8. Thus the attachment formations and opposing attachment formations are provided on opposing faces of the substrate in this example.

The elongate groove and/or rib 42 is configured to engage the complimentary groove and/or rib 42 of an adjacent substrate to form an interlocking connection therebetween. The attachment formation 40 provides a rigid attachment between each adjacent tile and provides a substantially weatherproof seal.

The substrate 6 may have a thickness between 1 mm and 100 mm, preferably, between 4 mm and 32 mm. Using techniques described herein the wall thickness of the majority of the substrate may be less than 10 mm or 8 mm. A thin and lightweight substrate is generally preferred.

The substrate is substantially waterproof. The substrate 6 may comprises a polymeric material. The polymeric material may comprise one or more of: polypropylene (PP); polyethylene (PE); high density polyethylene (HDPE); low density polyethylene (LDPE); polypropylene or another polyolefin; polyethylene terephthalate (PET); Acrylonitrile butadiene styrene (ABS), Polyvinyl Chloride (PVC), Polycarbonates (PC), Nylons, Ethylene propylene diene monomer (EPDM), Fluoropolymers, Silicone, Rubbers, Thermoplastic elastomers, Polyesters, Polybutylene terephthalate (PBT), Poly(meth)acrylates, Epoxies, or other such polymers. Additionally or alternatively, the substrate may comprise a composite material, for example, a fibre-reinforced composite, such as a carbon fibre composite.

In some embodiments, the substrate comprises a transparent material, for example, glass or a transparent polymer.

In other embodiments, the substrate comprises mineral based material, for example: stone; ceramic; or a cementitious material.

The substrate 6 may comprise materials with a high thermal conductivity, so that the substrate 6 acts a heat sink to transfer heat away from the solar power module 2, thereby increasing efficiency of the solar power cells. A composite substrate may be used having one or more particulate/filler material within a polymer matrix, e.g. to improve the properties of the substrate. In some examples, sand and/or metal/graphite filler may be mixed with the substrate polymer material.

The substrate may be made from recycled materials and/or may comprise materials that are readily recyclable. Recycled polymers of the type described above have been found to offer good characteristics.

In other embodiments, the substrate 6 consists of, or substantially comprises, a metallic material. Preferably, the metallic material comprises a lightweight metallic material, for example, aluminium or steel.

The rear/lowermost surface of the substrate 6 may comprise one or more protrusion, i.e. nib(s) 44, protruding therefrom (see FIGS. 4 and 8). The nib(s) 44 are integrally formed as part of the shape of the underside of the substrate 6. The nibs 44 are configured to allow attachment of the tile to onto roof batten or other similar support surface. The nibs 44 may comprise a flat abutment surface for alignment against a supporting frame/surface in use. An opposing surface of the/each nib 44 could be ramped or flat. The nibs 44 are provided adjacent an edge of the substrate in this example but could be provided elsewhere on the rear of the substrate as necessary.

The substrate 6 may comprise additional or alternative engagement features configured to allow attachment of the substrate 6 to a support structure. For example, the substrate may be attached to the support structure/frame using a bracket or rail system. The engagement features may comprise one or more: protrusions; ribs; grooves; holes; dovetails; or dovetail grooves.

The solar power module 4 may only overlie a portion of the substrate 6, e.g. as shown in the examples of FIGS. 3-6. The substrate 6 may comprise a head portion 34 which is not covered by the solar power module 4, i.e. extending beyond the perimeter/end of the module 4 such that its upper surface is exposed.

When installed for use, the head portion 34 will typically be overlaid by the lower end of an adjacent tile, as is conventional in laying tiles and therefore the solar power module is not required in this area, as it will be obscured on use.

The head portion may comprise one or more apertures 46, e.g. through hole, to allow insertion of a fastening member (e.g. screw or nail). The apertures may be formed during moulding of the substrate 6, thereby reducing the need to drill holes during installation, which may damage the tile The nib(s) 44 may additionally or alternatively be provided on the head portion 34.

In other embodiments, the solar power module 4 may overlie substantially the full area of the substrate 6. For example, in wall-mounted installations or non-roof cladding applications, an overlap may not be required, and so the full area of the tile 2 can be used for solar power generation. Even in some roof installations, it is possible that a side-by-side abutment of adjacent cladding members may be preferred to an overlapping tile arrangement. In such installations, the attachment formations 40 may still overlap/underlap with adjacent substrates to create a water tight construction.

In an embodiment, the solar module 4 is bonded to the substrate 6 using a bonding layer 15. The substrate 6 and module 4 may be joined together, or to one another, using thermocompression, chemical or mechanical bonding techniques, or a suitable combination of these aforementioned techniques.

The bonding layer 15 could comprise an adhesive, i.e. to form a chemical bond between the substrate and solar power module 4. Chemical bonding techniques may involve adhesives such as, for example, ethylene vinyl acetate (EVA) or other such glues, binders, epoxies, silicones, or various plastic agents which provide a firm and/or smooth bond, by means of evaporation of a solvent or by curing a bonding agent with heat, pressure, or time.

In some embodiments, the bonding layer 15 comprises a material, e.g. polymer material, with a melting point lower than a melting point of the material of both the substrate 6 and the solar power module 4, so that the bonding layer can be applied and melted in situ (to either join or detach the components) without thermal damage to the substrate 6 or the solar power module 4.

Thermocompression bonding techniques may involve, for example, a thin bonding layer/sheet to be applied to the surface of the base substrate and for that bonding layer to then be subjected to heat treatment process, using for example an in-line furnace, of a sufficient temperature to melt, or suitably soften, that bonding layer. Once softened/melted, the rear surface of the solar module section may be applied to the bonding layer with sufficient compressive force so to join the sections together. These sections may then be subjected to a cooling treatment to correctly set the bonding agent layer to form a secure bond between the base substrate section and the solar module section. The substrate and module 4 may be fused in this manner.

Suitable materials used for thermocompression bonding may include, for example, polymeric or metallic materials, although other materials or material composites may also be used.

In other examples, rather than providing a specific intermediate bonding layer, the substrate 6 may itself be applied to the rear of the solar power module 4. This may be achieved by moulding the substrate onto the solar power module 4. The formed module 4 may be located in a mould that comprise the relevant mould cavity for forming the substrate, such that the substrate material can be supplied to the cavity such that liquid substrate contacts the module 4 in the mould and thus cools so as to bond with substrate surface upon cooling.

Bonding methods of the kind described herein have been found to be advantageous in that they are resistant to de-bonding when the formed cladding module is exposed to cyclic thermal loading in use. The extremes of temperature that can be faced by a solar tile in a cyclic manner over its expected operational life means that delamination/debonding of the substrate and degradation of electrical connections within the tile present significant technical challenges. End-of-life de-bonding of the substrate is also a consideration if it is desired to enable recycling of the substrate.

Portions of the bonding layer 15 overlying the electrical connection 16 may be absent (see FIG. 2) to prevent distortion of the bonding layer 15 and/or damage to the electrical connection 16.

The lowermost surface of the solar module 4 adjacent the substrate (e.g. the back plate) may be roughened/textured. Additionally or alternatively, the uppermost surface of the substrate 6 adjacent the solar module 4 may be roughened/textured. The roughening of the surfaces allows the bonding layer 15 to ‘key’ with the substrate 6 and/or the solar module 4, thereby increasing the bond strength therebetween. The surface texture is typically of smaller length scale to the texture applied to the upper/outer surface of the solar power module 4.

The top surface of the base substrate and/or the bottom surface of the solar module may treated to achieve the desired surface effect for improved adhesion to the bonding agent/layer or the opposing surface of the module/substrate. Such a treatment may involve a texturing technique, such as mechanically or chemically etching, embossing, scoring or sand blasting, or may involve alternative treatments such as a plasma or corona treatment, in order to achieve the same result. The type and extent of process implemented may depend on the materials used to form the surfaces of those sections.

In some embodiments, only a portion, or portions, of the top surface of the base substrate, and/or the bottom surface of the solar module, are treated or textured as previously described, while the remainder of those surfaces may be untreated, or alternatively treated to achieve a different result. For example, the portion, or portions, of the base substrate not treated as previously described may be treated by other means to provide improved thermophysical properties.

In other embodiments, a top surface (e.g. a top layer) of the base substrate may be formed of a different material or materials than the rest of the base substrate.

In other embodiments, the solar module is mechanically attached to the substrate, for example, using mechanical fasteners or interference fit. One or more fastener may be used to secure the adjacent layers or a stack of layers together, such as, for example, a clip, screw or nail arranged to apply compressive force to hold the sections together.

Other joining methods may be considered, e.g., soldering, welding (e.g., ultrasonic welding, vibration welding, laser welding, and IR welding), vacuum lamination, ultrasonic bonding.

In an alternative embodiment, the solar module 4 is selectively attachable to the substrate 4. The solar module 4 may therefore be attached/detached to the substrate 6 as required. As shown in FIGS. 15 and 16, the solar module 4 and the substrate 4 are connected by a clip system, generally indicated at 60.

The clip system 60 comprises a first clip portion 62 connected to the solar module 4. The first clip portion 62 is configured to engage a second clip portion 64 provided on the substrate 6 to provide a connection therebetween.

In the present embodiment the first clip portion 62 is configured to overlie the solar module 4. The first clip portion 62 therefore loosely engages the solar module 4 to retain the solar module 4 against the substrate 6. The first clip portion 62 comprises a flange configured to overly the solar module 4. The first clip portions 62 may be curved (i.e. to provide a curved corner portion). The first clip portion 62 may therefore be L-shaped or arcuate. The first clip portion 62 may comprises a frame or the like, which is configured to engage a plurality of peripheral sides of the solar module 4. The frame may be U-shaped to engage three sides of the solar module 4. The clip system 60 may therefore help to seal the solar module 4 against the substrate 4.

Alternatively, the first clip portion 62 may comprises a plurality of discrete portions. For example, the first clip portions 62 may only be provided at select portions of the solar module (i.e. the clip system 60 is discontinuous about the periphery of the solar module 4). In alternative examples, the first clip portions 62 may be provided to collectively define a continuous frame.

During manufacture, the solar module 4 may be laid onto the substrate 6 and frame/discrete clips are overlaid the edges of the solar module 4 to provide a therebetween. This provide a quick and convenient means to the connect the solar module 4 and the substrate 6, without the use of adhesives or the like.

In alternative embodiments, the first clip portion 62 is integral or otherwise permanently attached to the solar module 4. For example, this may be provided by an adhesive or a mechanical means, such as a fastener.

The second clip portion 64 is integrally formed with substrate and/or otherwise permanently fixed thereto.

The first clip portion 62 comprises a latch member 66 (e.g. a pawl) configured to engage a corresponding keeper 68 on the second clip portion 64. The latch member 66 and the keeper 68 are provided in the inner sides 70a,b of the first and second clip portions respectively.

The latch member 66 is movably mounted to the first clip portion 62 to allow to latch member 66 to move past the keeper 68 and engage an underside 72 thereof. The latch member 66 may be mounted to the first clip portion 62 via a flexible portion 74 or a living hinge or the like. The flexible portion 74 comprises a portion of reduced thickness to provide flexibility thereof. The flexible portion 74 may be integral with the latching member and/or the first clip system 62. The latch member 66 is thus provided in a cantilever arrangement. The flexible portion 74 may comprise a living hinge or the like.

In other embodiments, the latch member 66 may be mounted by a hinge or pivot or the like.

In the embodiment shown in FIG. 15, the latch member 66 and the keeper 68 comprise respective angled surfaces 76a,b. The surfaces 76a,b face one another to aid the latch member 66 is sliding over the keeper 66. The latch member 66 and keep 68 comprises trapezoidal shapes. The clip system 60 thus provides a snap fit arrangement.

In the embodiment shown in FIG. 16, the latch member 66 comprises a rectangular shape and engages a corresponding rectangular shape in the keeper 68.

A back member 78 may be provided (see FIG. 16). The back member 78 is configured to engage the latch 66 to bias the latch member 66 into engagement with the keeper 68. This reduces the chance of unintentional disengagement of the latch 66 and the keeper 68. The back member 78 comprises an upstanding wall. The wall is mounted adjacent the keeper 68 such that the latch 66 is interposed the wall the keeper 68 when engaging the keeper 68. The wall is resiliently deformable, such that during connection of the latch mechanism, the wall deforms (i.e. bends or deflects) to accommodate the latch before it engages the keep 68.

The second clip portion 62 comprises an upstanding rim 80 an upper edge thereof. The rim 80 is configured to engage the inner side of the first clip portion 62 to provide a seal therebetween. As shown in FIG. 16, the rim 80 is may engage the latch 66/flexible portion 74 to provide a seal therebetween.

In the present embodiment, the latch mechanism cannot be unlatched by the user. The power module power 4 and the substrate are therefore attachable but not detachable in normal use. If disassembly is required, then the latch mechanism and/or portions of the first/second clip system must be deformed or destroyed. Thus, once disassembled, the tile connected be reassembled. Typically, this will occur by fracture of the latch 66 and/or the flexible portion 74. For example, the latch 66 and/or the flexible portion 74 may comprise one or more weakness (i.e. is frangible), such as perforations or a narrowed neck. Alternatively, the weakness may be provided by the general reduced thickness of the flexible portion 74 and/or a living hinge therein.

This arrangement prevents tampering or unauthorised dismantling of the tile 2 after manufacture, however, it allows the solar module 4 and the substrate 6 to be separated once disposed of for recycling etc.

In some embodiments, the latch may be unlatchable, however, the use of special tool or the like is required. For example, an aperture may be provided adjacent the keeper 68, thus allowing the latch 66 to be pushed out therefrom. The aperture may be shaped such that an unconventional tool cannot be inserted therein.

The latch mechanism may extend along the full length clip system 60 (i.e. is continuous there along). The latch 66 may therefore provide a skirt like member. Alternatively, the latch mechanism may only be provided in discrete/select portions of the clip system 60.

Referring back to FIGS. 1 and 2, the substrate 6 may comprise an upstanding lip 36. The upstanding lip 36 is configured to surround/engage the edge of the solar power module 9 to protect the edges from mechanical damage and/or ingress of moisture. The upstanding lip 36 may form a rim surrounding each edge of the solar power module 4. In some embodiments, the upstanding lip 36 surrounds three sides of the solar power module, leaving the side of the solar power module 4 adjacent the head portion 34 exposed.

The upstanding lip 36 extends a length substantially the same height as the solar power module 4, such that the top of lip 36 is flush with the upper surface of the solar power module 4.

The tile 2 may comprises a facia plate 38. The facia plate 38 is arranged to overly the edge of the top surface of the solar power module 4 to seal the edge of the solar power module 4 against the substrate 6 and/or lip 36 and prevent the ingress of moisture etc. The facia plate 38 overlies/engages the head portion 34 and only contains a portion of the solar power module 4 adjacent the head portion 34. In some embodiments, the facia 38 may comprise a frame configured to seal plurality of edges (e.g. each edge) of the solar power module 4. For example, the facia 38 may form part of the clip system 60.

A shown in FIGS. 17 and 18, the facia plate 18 is selectively attachable to the substrate 6. The facia plate 38 comprises a plurality of plugs 82 (e.g. rods, protrusions, pins, bolts or the like) configured to be received in corresponding recesses 84 in the substrate to provide a connection therebetween.

The connection may prevent tampering or unauthorised dismantling of the tile 2. For example, the plugs 82 may be secured in a permanent fashion, such as using adhesives. Alternatively, the plugs 82/recess 84 may be configured to be destructible or permanently deformable (e.g. using latches, barbs etc.) to allow disconnection thereof, as previously described.

The length of the plugs 82 may vary. For example, they may vary according to the depth of the portion of the substrate 6 into which they extend.

The facia 38 is configured to overlap a portion 4a of the solar module 4. The solar module portion 4a is offset (i.e. recessed) from the remainder of the solar module 4, such that facia 38 lies flush with the solar module 4. The facia 38 comprises a recess 86 on an underside thereof to accommodate the solar module portion 4a. One of the plugs 82a may be configured to extend through the solar module portion 4a to secure the solar module 4 to the substrate 6.

A recess 86 is provided adjacent the interface between the solar module 4 and the solar module overlap portion 4a. The recess 86 may allow electrical connection etc. to pass from the solar module 4 into the substrate 6.

In some embodiments, the facia plate is substantially transparent/translucent. A cover/facia layer, e.g. an outer layer may be provided.

Any exposed portions of the substrate may be UV resistant or treated/coated to improve UV resistance in the manner described above in relation to the solar module 4.

The substrate 6 comprises a cavity 18 configured to receive the electrical junction 16. The cavity 18 is formed as a blind hole or enclosed recess extending from the uppermost surface of the substrate, i.e. facing the underside of the solar module 4.

In other embodiments, the cavity 18 is offset from the uppermost surface of the substrate such that the cavity 18 is substantially enclosed by the substrate 6.

The cavity 18 is configured to house the electrical connector 16. One or more of the junction box 20; the electrical lead 24; and/or the electrical terminal 22 are therefore accommodated within the cavity 16. The cavity is configured to substantially seal the electrical junction 16 therein (i.e. the electrical connector 16 is sealed between the solar module 4 and the substrate 6). The seal may be substantially watertight to prevent the ingress of moisture etc., thus preventing/mitigating damage to the electrical components of the electrical connection and/or solar module.

The cavity 18 may be such shaped to conform to the shape and/or size of the electrical connector 16. For example, the cavity 18 may provide a close fit with one or more of: the shape/size of the junction box 20; the electrical leads 24; and/or the electrical terminal 22. In other examples, the junction box housing could be dispensed with and instead the cavity 18 of the substrate could house the junction box internal components. The cavity 18 may be sized to accommodate movement and/or increase in size of the electrical connectors 16 due to thermal expansion/contraction of the solar power module 4 and/or the electrical connector 16.

The cavity 18 may comprise a wider body portion and a narrower neck portion. The wider body portion houses the junction box. The narrower neck portion leads to the peripheral edge of the substrate and houses the electrical terminal 22 depending from the junction box.

The substrate 6 may comprise an upstanding wall 26 forming part of the cavity 18 adjacent an edge of the substrate comprising the cavity 18. The upstanding wall 26 comprises an aperture 28 configured to receive the electrical terminal 22 and permit an end 30 of the electrical terminal 22 to be accessible from outside the substrate 6.

The cavity opens at, or in a direction facing, a peripheral edge of the substrate 6/tile 2. The electrical terminal 22 is therefore provided at a peripheral edge/end of the substrate 6/tile 2. The terminal 22 is fully contained within the cavity 18 (i.e. only the end of the terminal 22 is exposed).

The end 30 of the electrical terminal 22 may be configured to lie flush with the outer edge of the upstanding wall 26 (or at least not protrude therefrom), for example, to prevent accidental damage of the electrical terminal 22. The terminal 22 is therefore planar/flush with the edge of the substrate 6/tile 2.

The electrical terminal 22 is configured to be sealed against the aperture 28 to prevent the ingress of moisture etc. into the cavity 18. The electrical terminal 22 may comprise a seal or gasket 31 provided between the aperture 28/upstanding wall 26 and the electrical terminal 22 to enhance the seal. Additionally or alternatively, the seal may be provided by the close fit between the aperture 28/cavity 16 and the terminal 22 and/or the leads 24.

The enclosed cavity 18 within the substrate on the underside of the solar power module 4 is beneficial in providing secure electrical terminals 22 embedded in the substrate and exposed at/proximal the peripheral edge of the assembled tile/cladding member. This protects the electrical terminals from impact or yanking, as well as avoiding flexing/stressing or exposure of the cables in use which can lead to degradation of the electrical connection. It also means that electrical leads for connecting up the tiles during installation can be provided separately from the tile itself, rather than requiring trailing leads that are integral with the tile.

The depth of the peripheral edge, e.g. a short edge of a rectangular tile, is particularly convenient for the location terminals, ensuring that all connection points for all tiles are accessible from the same direction during installation.

The upstanding wall 26 in this example is flush with (i.e. part of) the peripheral edge of the tile/substrate. In other examples, the upstanding wall 26 could be retracted slightly within the perimeter of the substrate, e.g. close to or adjacent the corresponding edge of the substrate/tile but not flush therewith. In this regard the electrical terminals 22 may still face outwardly towards the tile edge and be accessible via the edge of the tile but may be better protected from accidental damage by a slight overhang of the upper surface of the substrate.

In some embodiments, the cavity 18 is accommodated within the through thickness of the substrate 6, such that the lowermost surface of the substrate is substantially flat.

In other embodiments where the substrate is thinner than the junction box, the lower surface of the substrate may protrude outwardly to accommodate the cavity (as shown in FIG. 1). The outward protrusion may form part of the nib (i.e. so that the cavity is contained within the nib region).

As can be seen in FIG. 12, the provision of a long head section 34 can result in the cavity 18 and its contents being offset from beneath the solar module 4. In such examples, the electrical connection layer 12 (e.g. PCB) and backing layer 14 are extended beyond the extent of the other layers of the module 4 so as to span the head section 34. The electrical connection layer 12 thus provides the electrical connection between the solar cells 10 and the electrical connection 16 towards the edge of the substrate. That is to say, the electrical connection layer 12 may be longer than the solar cell layer 10.

Turning now to FIGS. 8 and 9, the substrate 6 may comprise a plurality of discontinuities/recesses 32 extending therethrough. The recesses are configured to permit the flow of air through or into the substrate 6, i.e. onto the rear of the solar power module 4, thereby transferring heat away from the substrate 6 and the solar power module 4 in use. The recesses also increase the surface area of the substrate that is exposed to promote cooling by convection.

The recesses 32 may comprises blind holes or depressions, extending from the lower surface of the substrate 6. The depressions could comprise troughs, grooves, dimples or the like. Additionally or alternatively, the recesses may comprise through holes extending between the upper and lower surface of the substrate 6.

The recesses 32 may only be located in portions of the substrate 6 overlaid by the solar power module 4, e.g. beneath the substrate. The recesses 32 may be absent in the portion of the substrate comprising the cavity 18 and/or the head portion 34. The recesses 32 may be absent in a central portion of the substrate.

The diameter and/or packing density of recesses 32 may be varied across the substrate. For example, the heat density in a given portion of the substrate 6 of solar power module 4 may be determined (either by measurement or modelling etc.). The diameter and/or packing density may be adjusted accordingly, such that diameter and/or packing density in the given portion is proportional to (or otherwise based on) the heat density in the given portion of the substrate 6.

The recesses 32 are provided over an area of the rear of the substrate, for example spanning collectively at least 5%, 10%, 20%, 30%, 40% or 50% of the area of the solar power module 4 or solar cell layer 10 thereof. The recesses may have uniform spacing and/or may be provided in a grid like array.

The recesses 32 may be arranged in a hexagonal, or other polygonal, array. Such an arrangement allows a large density of holes without comprising structural integrity. It has been found that the structural integrity of the substrate remains sufficient to support the solar power module even when perforated in this manner to allow better cooling characteristics. Natural convective airflow or a forced air flow in the cavity behind the substrate can ensure the solar power module 4 is maintained within a desired operating temperature range. This can significantly contribute to increased life and greater operational efficiency of the solar power module, particularly in the case where the tile is devoid of an outer glass layer. The reduced material weight of the substrate is also a benefit.

In alternative embodiments, thermal dispersion is achieved by varying the thickness of the substrate 6 accordingly. For example, high temperature areas may comprise a low thickness to aid with heat transfer and low temperature areas may comprises a greater thickness. Rather than an array of recesses, a simple region of reduced wall thickness could be provided in the substrate behind the solar power module to promote heat transfer away from the module.

A plurality of solar power modules 4 may be provided on a single substrate 6. The solar power modules 4 may be arranged in an array and configured to emulate an array of individual tiles (i.e. modular tiles). The substrate 6 may have features configured to emulate a feature between conventional tiles, for example, a groove to emulate a gap or grout, to further enhance the effect of having multiple tiles. An example is shown in FIG. 10, in which it can be seen that attachment formations 40 and/or fastening formations 46 of the type described above may be common to the whole substrate 6 comprising the plurality of modules 4 or tiles. A two-dimensional array of tiles is shown in FIG. 10 (i.e. a 3×3 array) but any array of two or more tiles could be produced. For example, a single row or single column of tiles may be used.

In FIG. 11 it is shown the electrical terminals 22 for the multi-module substrate are the same as for a single module as shown in FIG. 4. Thus the multi-module version offers ease of installation and reduced wiring burden. A single PCB board layer 12 could span a plurality of solar cell layers 10 within the solar power module 4 to this end, e.g. allowing a single junction box and electrical terminals for the whole array of solar cells.

FIG. 9 shows a rear view of a multi-module substrate have a plurality of arrays of cooling recesses 32, i.e. with an array provided behind each different solar cell layer.

In some embodiments, the solar power module 4 and/or substrate 6 are substantially transparent/translucent, such that the solar tile 2 is substantially transparent/translucent. For example, the solar power 4 may be affixed to a glass substrate or transparent polymer substrate.

The solar tile 2 may comprise one or more graphics layers 48 configured to display one or more graphics/colours. The graphics layer may be partially transparent/translucent to allow light to pass through the tile 2 and/or onto the solar power layer 10. Additionally or alternatively, the graphics layer comprises one or more of: a perforated sheet (e.g. Contra Vision®); a ‘dot-matrix’ style array; or an alternating opaque/transparent plurality of lines/patterns. The graphics layer may extend over the entirety of the tile 2 or may only extend over select portions of the tile 2 (e.g. to provide a logo).

The one or more graphics layers 48 may be located at any location on/within the tile 2, provided that the graphics are suitably visible. For example, the graphics layer 48 may be located: on the uppermost surface of the solar power module 4; within the solar power module 4; between the solar power module 4 and the substrate 6; embedded within the substrate 6; or on a lowermost surface of the substrate 6. In some embodiments, the graphics layer 48 is provided adjacent the solar power layer 10. In some embodiments, the graphics are printed directly onto the substrate 6.

In an embodiment shown in FIGS. 13 and 14, the solar power module 4 is affixed to a glass substrate 6. The glass substrate 6 forms a part of a window 50 of a building. The solar power module 4 may be affixed to a pre-existing window pane in situ, or the solar power module 4 may be affixed to the glass substrate and then the solar tile 2 (e.g. the glass and solar power module combination) is installed into the window as an integral unit.

The graphics layer 48 overlies the solar power module 4 and perforations/dot matrix provides a graphical image 52. The graphics layer 48 only absorbs/reflects a portion of the light entering the window 50, thereby allowing a portion of the light onto the solar power module 4 and/or into the building.

In other embodiments, the solar power module 4 or tile 2 is sandwiched between two transparent substrates. For example, the solar power module 4 is sandwiched between two glass panes of a double glazed window pane. The graphic layer 48 may be provided on/within the solar power module 4/tile 2, or on the outer surfaces of either of the glass panes.

In some embodiments, the solar power module 4/tile 2 is flexible, (i.e. the backing layer 14, solar power layer 10 and/or substrate are substantially flexible). For example, the solar power module 4/tile 2 is provided as a roll and then laid onto the substrate (e.g. window).

In other embodiments, the substrate 6 is opaque and/or the tile 2 is mounted to a substantially opaque structure (e.g. a billboard or a sign). The graphics layer 48 may be substantially opaque and may be positioned between the solar power layer 10 and the backing layer 14.

In other examples a graphics layer 48 could be provided as an outer/external layer over an opaque solar power module 4 and/or substrate 6.

The present invention provides a compact, self-contained and weatherproof tile. The encapsulation of the solar power layer provides a weatherproof solar power cell, thus increasing the efficacy and longevity of the solar cells.

Incorporating the electrical connections within the cavity in the substrate may provide a number of advantages:

The electrical connections are sealed within the substrate, thus significantly reducing exposure to the weather or moisture.

The invention reduces the chance of the electrical connections being damaged during transport or installation as they are maintained within the tile. For example, the electrical terminals do not protrude or dangle from the tile.

The tiles remain substantially flat as there are no protruding electrical connectors. Thus, the tiles can be more easily stacked for storage or transportation etc.

The lack of protruding electrical connections also allows greater flexibility in the manufacture and installation of the tile. For example, the tiles may be used in a pre-fabricated structure where hundreds of tiles may be used adjacent one another, without the problem of cables etc. becoming tangled and or damaged. The electrical connection between each tile may then be made once the pre-fabricated structure has been positioned into place.

The electrical terminals face the side edge of the cladding member, thereby improving cable management. This may reduce the likelihood of wires connecting the installed cladding members from resting on a roof felt and causing moisture to seep through the felt.

The use of holes in the substrate and/or thermally conductive backing layers increases the transfer of heat away from the solar power layer 8, thus increasing the efficacy and longevity of the solar power cells. The holes also reduce the effective weight of the substrate, thereby allowing easier installation and transportation, and reducing the amount of material required to manufacture the substrate.

The tiles have a natural look, therefore blending in with pre-existing tiles and/or surrounding structures.

The tile uses recycled/recyclable materials, thus reducing the carbon footprint of the tile. The use of an EVA bonding layer permits to the bonding layer to be melting such that the component layers of the solar tile be separated for recycling.

The solar tile provides a lightweight, durable tile, allowing the tile to have versatile applications. The solar tile may be used on structures (for example, roofs, walls or windows) and/or may be mounted to other frame-like support structures. The encapsulated module prevents damage of the power cells during manufacture, transport or installation.

The solar tile allows individual tiles to be replaced, thus allowing incremental replacement of the solar system. This reduces the need to replace a large portion of the system due to a single point failure, thereby reducing the wastage of functional portions of the system attached to the failure system.

The design also allows solar power generating cladding members to be formed in the same way as non-solar cladding members. A non-solar cladding module will omit the solar power module 4 and the electrical connectors but will have a visually similar outward appearance and texture to that of the solar module.

The non-solar (e.g. aesthetic) module may be bonded to the base substrate of the non-solar cladding unit in a similar manner to the solar module described herein. In some embodiments, the non-solar cladding unit may not have a module inserted, but the base substrate may be formed to have the appearance as though including a solar module, e.g. as an integral moulding. In any examples, a top surface of the base substrate or module may be treated, coated or laminated, so to have the same visual appearance as that of the solar cladding unit version.

An installed cladding system may thus have any desired combination of solar power and non-solar cladding members. The solar power cladding members will be electrically connected using leads in the manner described above, whereas the non-solar members will not. However each type of cladding member can be mounted in a common manner, thereby simplifying installation.

1. A solar cladding member comprising:
a solar power module, the solar power module encapsulated in a polymeric material and comprising a first surface arranged to be exposed to sunlight in use and an opposing surface affixed to a substrate;
an electrical junction configured to connect the solar power module to an electrical system for transfer of electrical power from the solar power module, the electrical junction located on the opposing surface of the solar power module adjacent the substrate;
where the substrate comprises a cavity facing the opposing surface of the solar power module, the cavity bounded by the substrate, and configured to accommodate and seal the electrical junction therein.

2. A solar cladding member according to claim 1, where the electrical junction comprises a junction box, the junction box accommodated within the cavity.

3. A solar cladding member according to claim 1, where the electrical junction comprises at least one electrical lead depending therefrom, the electrical lead accommodated within the cavity.

4. A solar cladding member according to claim 1, where the cavity opens at, or in a direction facing, a peripheral edge of the substrate.

5. A solar cladding member according to claim 1, where the electrical junction comprises at least one electrical terminal configured to receive an external electrical terminal, the electrical terminal accommodated within the cavity.

6. A solar cladding member according to claim 5, where the electrical terminal is provided at a peripheral side of the substrate.

7. A solar cladding member according to claim 5, where the electrical terminal lies flush with an outer edge of the substrate, such that the electrical terminal does not protrude therefrom.

8. A solar cladding member according to claim 5, where the electrical terminal is mounted within an aperture or recess in an outer wall of the substrate.

9. A solar cladding member according to claim 1, where the solar power module comprises a plurality of layers of polymeric material, the plurality of polymeric layers encapsulating a solar power layer comprising a solar power cell.

10. (canceled)

11. A solar cladding member according to claim 1, where the solar power module comprises a first layer configured to be exposed to the external environment in use, the first layer comprising polymeric material having a surface texture.

12. (canceled)

13. A solar cladding member according to claim 11, where the surface texture comprises a substantially uniform pattern of recesses in the first layer provided over a solar power cell area of the solar power module

14. A solar cladding member according to claim 13, wherein the first layer has a stippled texture.

15. A solar cladding member according to claim 13, wherein the surface texture comprises a first type of surface texture and the first layer comprising a further type of surface texture, the further type of surface texture comprising a non-uniform and/or aesthetic surface texture.

16. A solar cladding member according to claim 15, where the first type of surface texture comprises a micro-texture and the second type of surface texture comprises a macro-texture.

17. A solar cladding member according to claim 1, comprising a moulded and/or fused interface between the solar power module and substrate.

18. A solar cladding member according to claim 1, where the substrate comprises a polymeric material.

19. A solar cladding member claim 1, where the solar power module is bonded to the substrate using a bonding layer at the interface between the substrate and solar power module, where the bonding layer comprises a material with a melting point lower than a melting point of the material of both the substrate and the solar power module.

20. (canceled)

21. A solar cladding member according to claim 1, where the substrate comprises an upstanding lip, the lip surrounding at least one edge of the solar power module.

22. A solar cladding member according to claim 1 where the substrate comprises a plurality of recesses at least partially extending through the substrate behind the solar power module.

23. (canceled)

24. A solar cladding member according to claim 1, where the solar power module and substrate are selectively attachable to one another by a latch member, the latching member configured to allow attachment of the solar power module and configured to prevent detachment thereof once attached.

25. (canceled)

26. A solar cladding member according to claim 24, where a portion of the latch member, and/or a portion of the substrate and/or solar power module configured to engage the latch member in use, is configured to be destructible and/or permanently deformable to allow detachment of substrate and the solar power module.

27. A solar cladding member according to claim, where the latch member is configured to engage a keeper to provide attachment thereof, where the latch member is biased into engagement with the keeper via a back member configured to engage the latch member.

28. A solar cladding member according to claim 1, where the solar power module and substrate are attachable via a clip system, the clip system configured to engage and overlap one or more peripheral edges of the solar power module.

29. A solar cladding member according to claim 1 comprising a facia, the facia configured to engage the substrate and to overly a portion of the solar power module such that the solar power module is interposed between the facia and the substrate.

30. A solar cladding member according to claim 29, where the facia is selectively attachable to the substrate and/or solar power module.
